(19) United States
(12) Patent Application Publication
(10) Pub. No.: US 2012/0070984 A1
(43) Pub. Date: Mar. 22, 2012

(54) METHOD FOR FORMING ELECTRODE STRUCTURE

(75) Inventors: Wen-Chung Tang, Hsinchu City (TW); Yao Peng, Hsinchu City (TW); Chia-Chun Yeh, Hsinchu City (TW); Yao-Chou Tsai, Hsinchu City (TW)

(73) Assignee: E Ink Holdings Inc., Hsinchu City (TW)

(21) Appl. No.: 13/105,405

(22) Filed: May 11, 2011

(30) Foreign Application Priority Data
Sep. 20, 2010 (TW) 099131823
Oct. 11, 2010 (TW) 099134631

(51) Int. Cl. H01L 21/283

(52) U.S. Cl. 438/669; 257/E21.159

(57) ABSTRACT

In a method for forming an electrode structure in a display device, e.g. a source, drain or gate electrode or a pixel electrode, a photoactive conductive layer, which includes conductive material containing photoactive material, is formed above a substrate of the display device. The photoactive conductive layer is then patterned with a photo-mask and partially removed without the presence of a photo-resist to form the electrode structure.

The present invention relates to a method for forming a conductive structure of a display device, and more particularly to a method for forming an electrode structure of a thin-film transistor.

### BACKGROUND OF THE INVENTION

A thin-film transistor is generally defined with a gate electrode and source/drain electrodes isolated from one another with insulating material. Depending on the position of the gate electrode relative to the source/drain electrodes, a thin-film transistor may have a bottom-gate structure or a top-gate structure. FIGS. 1A and 1B are cross-sectional views schematically illustrating two examples of a thin-film transistor device with a bottom-gate structure. FIG. 1C is a cross-sectional view schematically illustrating an example of a thin-film transistor device with a top-gate structure.

In the example illustrated in FIG. 1A, a substrate 101 is provided, and a metal layer 103 is applied onto the substrate 101, then patterned and etched so as to form a gate structure. Subsequently, a dielectric layer 104 and a semiconductor layer 102 overlie the substrate with the gate structure, and then another metal layer 203 is applied onto the resulting substrate, then patterned and etched so as to form the source and drain structures.

The example illustrated in FIG. 1B is similar to that illustrated in FIG. 1 except that the semiconductor layer 102 overlies other than underlies the metal layer 103 for forming the source and drain structures.

In the example of FIG. 1C, the metal layer 103 applied onto the substrate 101 is patterned and etched so as to form the source and drain structures first. Subsequently, the semiconductor layer 102 and dielectric layer 104 overlie the substrate with the source and drain structures, and then the metal layer 103 for forming the gate structure is applied onto the resulting substrate, patterned and etched.

For fabricating any of the above-described thin-film transistors, it is necessary to form, pattern and etch metal layers so as to obtain desired electrode structures. FIGS. 2A, 2B, 2C, 2D, 2E, 2F and 2G are cross-sectional views schematically illustrating a method for forming an electrode structure of a thin-film transistor according to prior art. The method substantially includes film-forming, patterning and etching phases. In the film-forming phase, substrate 101 is provided, as illustrated in FIG. 2A, and micro-/nano-scale metal layer 103 is spin-coated onto the substrate 101, as illustrated in FIG. 2B. Then in the patterning phase, a photo-resist layer is spin-coated and subjected to exposure and development so as to be partially removed, as illustrated in FIGS. 2C, 2D and 2E. In the etching phase, the metal layer 103 uncovered by the photo-resist is etched off, as illustrated in FIG. 2F, and after the desired metal pattern is formed, the remaining photo-resist layer is removed, as shown in FIG. 2G.

According to the prior art, two spin-coating operations respectively for forming the micro-/nano-metal layer 103 and photo-resist layer 105 are performed on the substrate 101. Afterwards, the photo-resist layer 105 needs to be removed by an additional operation. In addition, high temperature vapor deposition and processes which cannot be accomplished by common TFT manufacturing apparatus, e.g. laser inject and laser induced thermal imaging (LITI), are involved. The prior art process is complicated so as to be time consuming and costly.

### SUMMARY OF THE INVENTION

Therefore, an object of the present invention is to provide a simplified method for forming an electrode structure.

In accordance with an aspect of the present invention, a method for forming an electrode structure includes steps of: providing a substrate; forming a photoactive conductive layer on the substrate; patterning the photoactive conductive layer with a photo-mask; and partially removing the patterned photoactive conductive layer to form the electrode structure.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A and 1B are cross-sectional views schematically illustrating examples of a thin-film transistor device with a bottom-gate structure;

FIG. 1C is a cross-sectional view schematically illustrating a thin-film transistor device with a top-gate structure;

FIGS. 2A, 2B, 2C, 2D, 2E, 2F and 2G are cross-sectional views schematically illustrating a method for forming an electrode structure of a thin-film transistor according to prior art;

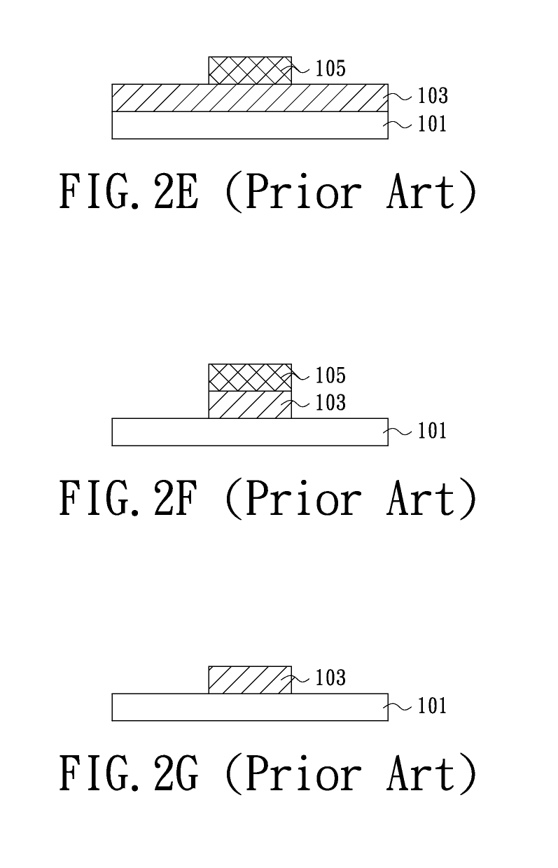

FIG. 3 is a flow chart illustrating a method for forming an electrode structure of a thin-film transistor device according to an embodiment of the present invention;

FIGS. 4A˜4D are cross-sectional views schematically illustrating a first example of the embodiment according to the present invention, as illustrated in FIG. 3; and

FIGS. 5A and 5B are cross-sectional views schematically illustrating a second example of the embodiment according to the present invention, as illustrated in FIG. 3.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

In order to simplify the method for forming an electrode structure of a thin-film transistor, a specific photoactive conductive layer is used as the electrode layer and patterned to form the electrode structure.

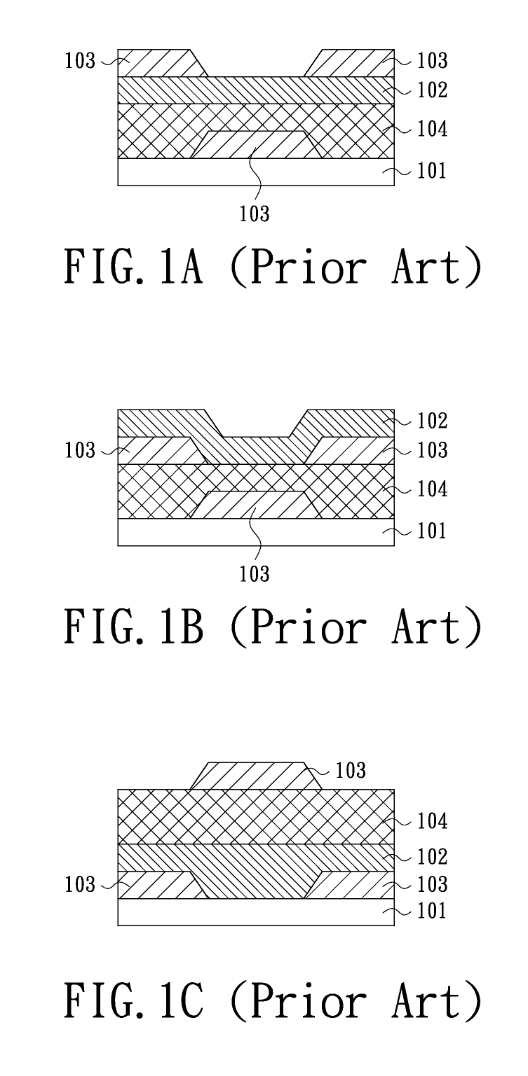

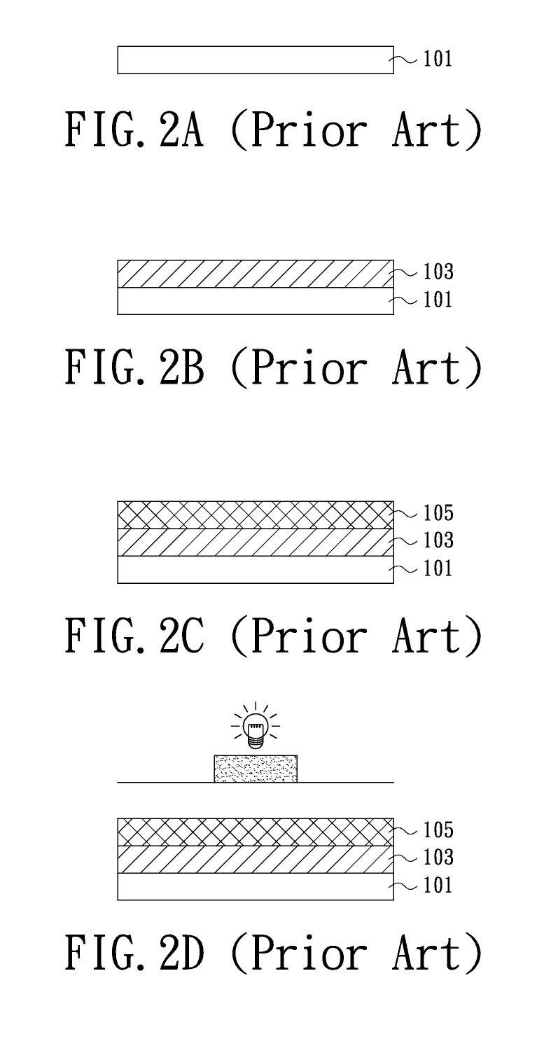

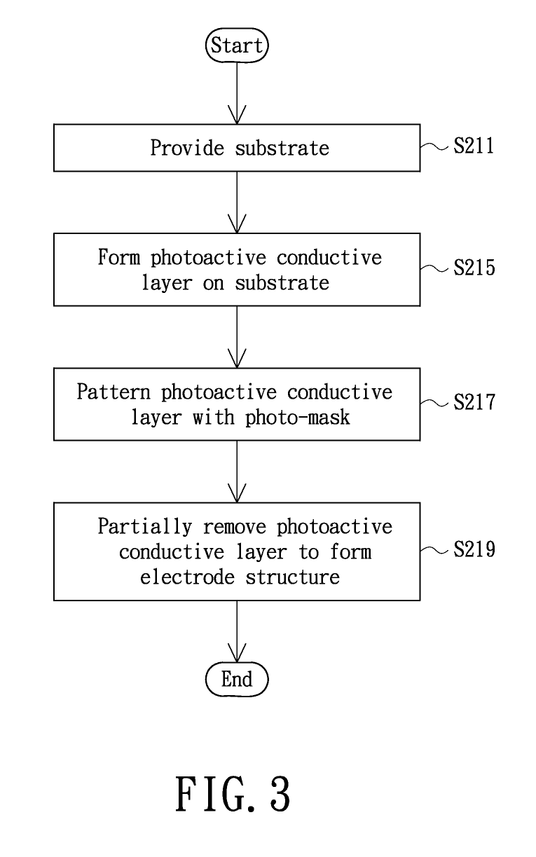

Please refer to FIG. 3, in which steps of a method for manufacturing a thin-film transistor according to an embodiment of the present invention are illustrated. What is illustrated below is for forming any of the source, drain and gate structures of a thin-film transistor device shown in FIGS. 1A, 1B or 1C. It is to be noted that the configurations of thin-film transistor devices as shown are for illustration purpose only, and the method according to the present invention may be applied to any other suitable configuration of thin-film transistor device. Furthermore, the method according to the present invention may also be used to form an electrode structure rather than the source, drain or gate electrode of a thin-film transistor. For example, the method may be used for forming a pixel electrode of a display panel.

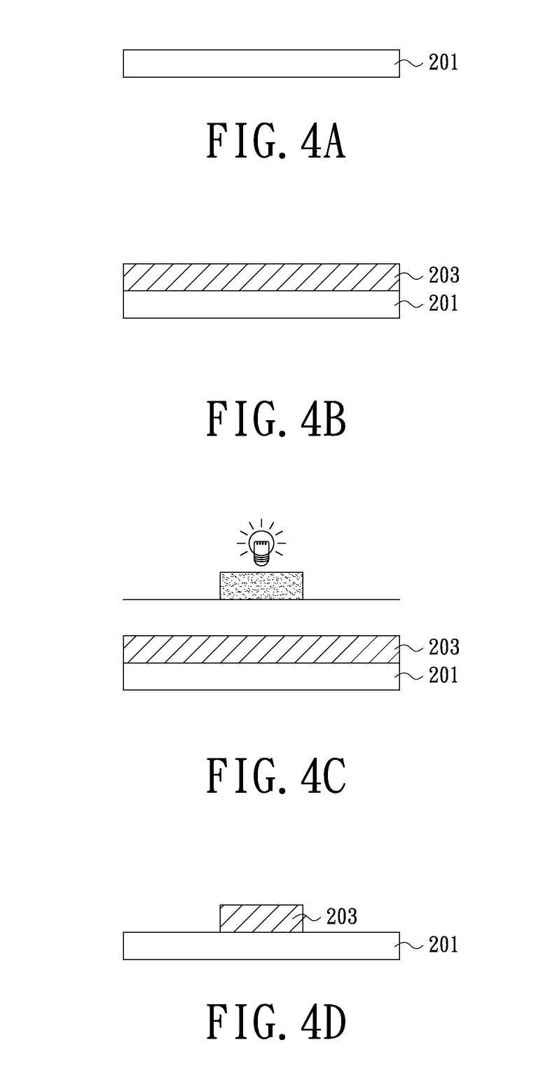

Hereinafter, an example is given with reference to FIG. 3 and FIGS. 4A˜4D for better understanding the present invention. FIGS. 4A˜4D schematically illustrate an example of the resulting structures corresponding to the steps described in the flow chart of FIG. 3. First of all, a substrate 201, e.g. a glass substrate, is provided (S211; FIG. 4A). Then a photoactive conductive layer 203 is formed on the substrate 201 (S215; FIG. 4B). Since the conductive layer 203 is photoactive, it may be subjected to patterning and photolithographic procedures without the presence of a photo-resist layer (S217; FIG. 4C). According to the desired pattern, an etching procedure is performed to partially remove the photoactive conductive layer while remaining a portion of the photoactive conductive layer so as to form the electrode structure as shown (S219; FIG. 4D).

In the above-described example, the photoactive conductive layer 203 is formed by spin-coating a liquid phase of conductive material, in which one or more photoactive material is mixed, onto the substrate 201, and dried to form the conductive film. The conductive material and the photoactive material are selected depending on practical requirements. For example, the conductive material may be micro-/nano-scale metal such as gold (Au), Silver (Ag), nickel (Ni), or any other suitable material, and the photoactive material may be Bezocyloutene (BCB), Diazonaphthoquinone (DNQ), or any other suitable material. It is to be noted that since in this embodiment, the photoactive conductive layer is applied onto the substrate by way of spin-coating, it is desirable that the properties of the conductive material and photoactive material are suitable to be spin-coated. Alternatively, other kinds of film-forming method may also be used for forming the photoactive conductive layer, and then the conductive material and photoactive material should be selected based on the property of the specified film-forming method.

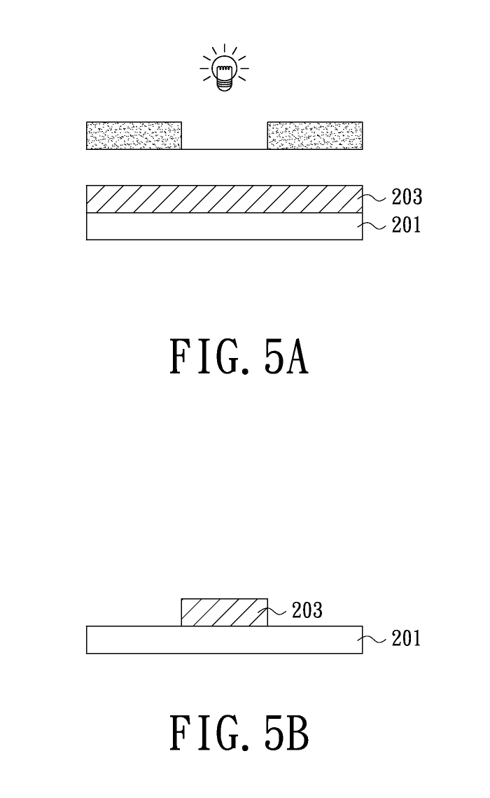

In the example described with reference to FIGS. 4A˜4D, the photo mask provided for defining the electrode structure has a shape and size consistent to the desired electrode structure (see FIGS. 4C and 4D). Alternatively, the embodiment of the method for forming an electrode structure as illustrated in FIG. 3 is feasible by having the shape and size of photo mask complementary to those of the electrode structure, as illustrated in FIGS. 5A and 5B, on the condition that a proper photoactive material is contained in the conductive material.

As described above, the method can be simplified by using a photoactive conductive layer as an electrode layer. In a case that the photoactive conductive layer is applied onto a base structure by spin-coating in a spin coater, it is preferable that one or more preceding or subsequent film, e.g. a dielectric layer such as a gate insulator or a passivation layer, is also applied by spin-coating in the spin coater. It is further advantageous in manufacturing a soft display by using a low-temperature spin-coating process in lieu of a high-temperature vapor deposition process for forming the film.

Furthermore, for further assuring of the low-temperature process, it is preferable that the semiconductor layer is made of amorphous silicon (a-Si), or applied onto the base structure by low-temperature sputtering. The material of the semiconductor layer, for example, may be oxide metal semiconductor such as Indium gallium zinc oxide (IGZO), indium zinc oxide (IZO), Zn Oxide, Magnesium and Zinc Oxide (Mg—Zn Oxide), Cadmium and Zinc Oxide (Cd—Zn Oxide), or Cadmium oxide (Cd Oxide).

According to the present invention, a simplified method for forming an electrode structure is provided. In addition, the present invention also teaches how to complete formation of a thin-film transistor device within a yellow zone that improves the production rate under a relatively low temperature (lower than 200 degree Celsius) condition.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for forming an electrode structure, comprising steps of:
providing a substrate;
forming a photoactive conductive layer above the substrate;
patterning the photoactive conductive layer with a photo-mask; and
partially removing the patterned photoactive conductive layer to form the electrode structure.

2. The method for forming an electrode structure according to claim 1, wherein the photoactive conductive layer is made of a metal material, in which a photoactive material is mixed.

3. The method for forming an electrode structure according to claim 2, wherein the metal material is gold (Au), Silver (Ag), or nickel (Ni).

4. The method for forming an electrode structure according to claim 2, wherein the photoactive material is Bezocyloutene, or Diazonaphthoquinone.

5. The method for forming an electrode structure according to claim 1, wherein the substrate is a substrate of a thin-film transistor device for forming thereon a gate, source or drain structure, or the substrate is a substrate of a display panel for forming thereon a pixel electrode structure.
